(19) United States
(12) Patent Application Publication
(10) Pub. No.: US 2025/0279596 A1
(43) Pub. Date: Sep. 4, 2025

(54) TERMINAL BLOCK AND BUS BAR CONNECTION STRUCTURE

(71) Applicant: HONDA MOROR CO., LTD., Tokyo (JP)

(72) Inventors: Takahiro HAGIMOTO, Saitama (JP); Kenji Kimura, Aichi (JP)

(21) Appl. No.: 19/044,741

(22) Filed: Feb. 4, 2025

(30) Foreign Application Priority Data
Mar. 4, 2024 (JP) 2024-032394

(51) Int. Cl. H01R 9/24; H01R 9/18; H05K 7/20

(52) U.S. Cl. CPC H01R 9/24; H05K 7/20472; H01R 9/18; H05K 7/2049

(57) ABSTRACT

A terminal block supports a bus bar connection portion as a connection portion between a plurality of bus bars. The heat transfer portion is attached to the terminal block body so as to be exposed on both sides in a Z direction from the terminal block body. The heat transfer portion allows the bus bar connection portion to be fastened to an end portion thereof on the Z+side. The protruding portion protrudes from the terminal block body in an X direction and can be fastened to the base. A heat transfer sheet being an insulator can be interposed between the heat transfer portion and the base. A bus bar other than the plurality of bus bars and a heat transfer sheet being an insulator can be interposed between the protruding portion and the base, in this order from the Z+ side.

### This application is based on and claims the benefit of priority from Japanese Patent Application No. 2024-032394, filed on 4 Mar. 2024, the content of which is incorporated herein by reference.

### BACKGROUND OF THE INVENTION

### Field of the Invention

The present invention relates to a terminal block for supporting a connection portion between a plurality of bus bars, and a bus bar connection structure using the terminal block.

### Related Art

In some bus bar connection structures, a connection portion between bus bars is physically connected to a cooling portion to cool the bus bars while being electrically insulated from the cooling portion.

### Patent Document 1: Japanese Patent No. 6623392

### SUMMARY OF THE INVENTION

According to such a bus bar connection structure, although the connection portion between the bus bars can be cooled, the bus bars can be cooled only at one location, that is, at the connection portion. Therefore, in a case where another bus bar around the connection portion between the bus bars is also cooled, a cooling structure for cooling the other bus bar is additionally required. Accordingly, the peripheral structure of the connection portion between the bus bars becomes complicated.

In response to the above issue, an object of the present invention is to simplify the peripheral structure of a connection portion between bus bars.

The present inventors have found that when a part of another bus bar is pressed against a heat transfer sheet in a terminal block for supporting the connection portion between bus bars, the peripheral structure of the connection portion between the bus bars can be simplified, and have reached the present invention. The present invention relates to the following terminal blocks according to a first aspect to a third aspect and bus bar connection structures according to a fourth aspect and a fifth aspect.

A first aspect of the present invention is a terminal block for supporting a bus bar connection portion as a connection portion between a plurality of bus bars. The terminal block includes: a terminal block body, being an insulator, configured to be fastened to a base, being a conductor, from a Z+ side as one side in a predetermined Z direction;
a heat transfer portion, being a conductor, that is attached to the terminal block body so as to be exposed on both sides in the Z direction from the terminal block body and that is configured such that the bus bar connection portion can be fastened to an end portion thereof on the Z+ side; and a protruding portion, being an insulator, that protrudes from the terminal block body in an X direction orthogonal to the Z direction and that is configured to be fastened to the base. The terminal block is configured to allow a heat transfer sheet, being an insulator, to be interposed between the heat transfer portion and the base. The terminal block is configured to allow a bus bar other than the plurality of bus bars and a heat transfer sheet, being an insulator, to be interposed between the protruding portion and the base, in this order from the Z+ side.

According to the present configuration, a part of another bus bar can be pressed against the heat transfer sheet and cooled by the protruding portion of the terminal block for supporting the bus bar connection portion. Accordingly, the terminal block for supporting the bus bar connection portion and a pressing member for pressing a part of the other bus bar against the heat transfer sheet can be integrated into one member. As a result, the peripheral structure of the connection portion between the bus bars can be simplified.

In a second aspect of the terminal block according to the first aspect, the terminal block body extends in a Y direction orthogonal to the X direction and the Z direction. Both side portions of the terminal block body sandwiching the heat transfer portion in the Y direction are configured to be fastened to the base. The protruding portion protrudes in the X direction from an intermediate portion in the Y direction, of the terminal block body.

According to the present configuration, the both side portions of the terminal block body sandwiching the heat transfer portion in the Y direction, and the protruding portion protruding in the X direction from the intermediate portion in the Y direction, of the terminal block body are fixed to the base, so that the terminal block is fixed to the base in a well-balanced manner.

In a third aspect of the terminal block according to the first or second aspect, the terminal block body and the protruding portion are integrally formed.

According to the present configuration, the configuration of the terminal block can be simplified.

A fourth aspect of the present invention is a bus bar connection structure including the terminal block according to any one of the first to third aspects. The heat transfer sheet, being the insulator, is interposed between the heat transfer portion and the base. The bus bar other than the plurality of bus bars and the heat transfer sheet, being the insulator, are interposed between the protruding portion and the base, in this order from the Z+ side.

According to the bus bar connection structure of the present configuration, as in the case of the terminal block according to the first aspect, the peripheral structure of the bus bar connection portion can be simplified.

In a fifth aspect of the bus bar connection structure according to the fourth aspect, the heat transfer sheet interposed between the heat transfer portion and the base is a part of a predetermined heat transfer sheet. The heat transfer sheet interposed between the protruding portion and the base is an other part of the predetermined heat transfer sheet.

According to the present configuration, the heat transfer sheet interposed between the heat transfer portion and the base and the heat transfer sheet interposed between the protruding portion and the base are integrated into one predetermined heat transfer sheet, so that the number of components of the bus bar connection structure can be reduced.

As described above, according to the configurations of the first and fourth aspects, the peripheral structure of the bus bar connection portion can be simplified. Furthermore, according to the configurations of the second, third, and fifth aspects that cite the first or fourth aspect, the respective additional effects can be obtained.

### BRIEF DESCRIPTION OF THE DRAWINGS

FIG. 1 is a perspective view showing a terminal block according to a first embodiment and its periphery;

FIG. 2 is a plan view showing the terminal block and its periphery;

FIG. 3 is a plan view showing a state in which a bus bar connection portion is attached to the terminal block;

FIG. 4 is a cross-sectional view taken along line fg4-fg4 in FIG. 3;

FIG. 5 is a cross-sectional view taken along line fg5-fg5 in FIG. 3; and

FIG. 6 is a perspective view showing a terminal block of a comparative embodiment and its periphery.

### DETAILED DESCRIPTION OF THE INVENTION

Hereinafter, embodiments of the present invention will be described with reference to the drawings. However, the present invention is not limited to the following embodiments, and can be modified and implemented as appropriate within a range not departing from the gist of the present invention.

### FIRST EMBODIMENT

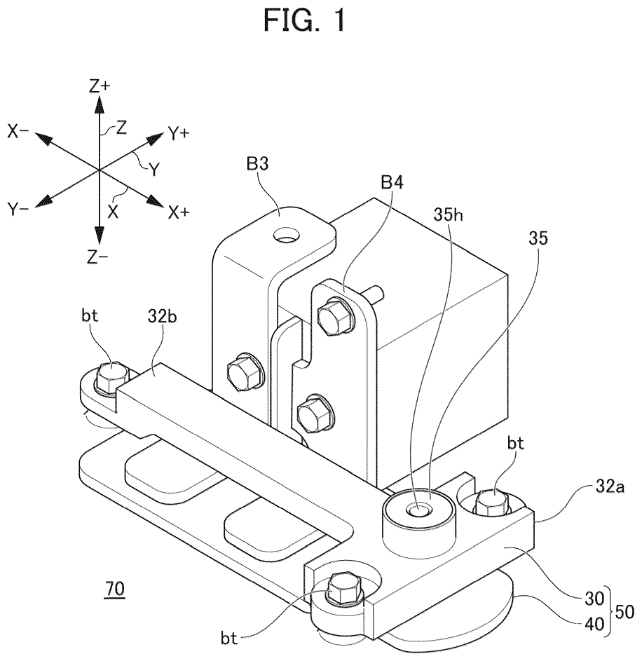

A bus bar connection structure 50 of the present embodiment shown in FIG. 1 is a structure for holding four bus bars B1 to B4. Hereinafter, the predetermined three directions orthogonal to each other are referred to as an “X direction”, a “Y direction”, and a “Z direction”. One side in the X direction is referred to as an “X-side”, and the opposite side is referred to as an “X+side”. One side in the Y direction is referred to as a “Y-side”, and the opposite side is referred to as a “Y+side”. One side in the Z direction is referred to as a “Z-side”, and the opposite side is referred to as a “Z+side”. Note that, in the present embodiment, the “Z+side” is the “upper side”, and the “Z-side” is the “lower side”. Therefore, the X direction and the Y direction are horizontal directions.

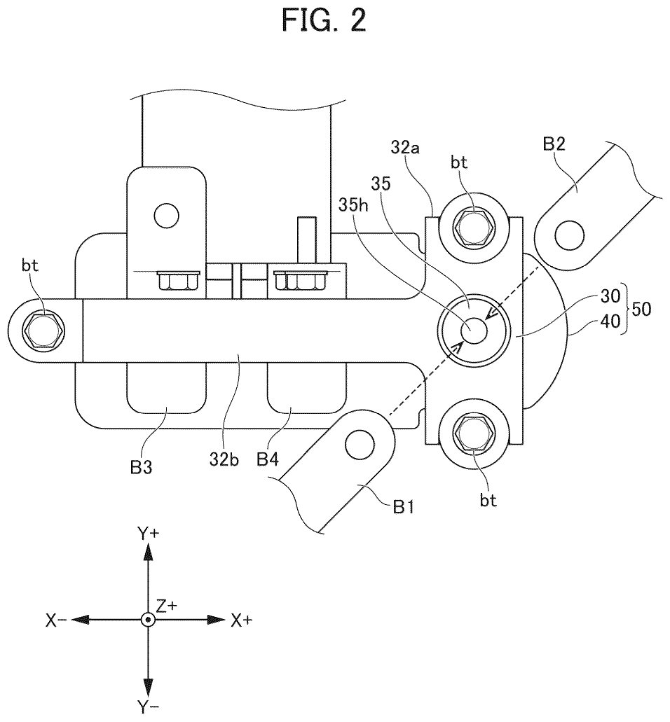

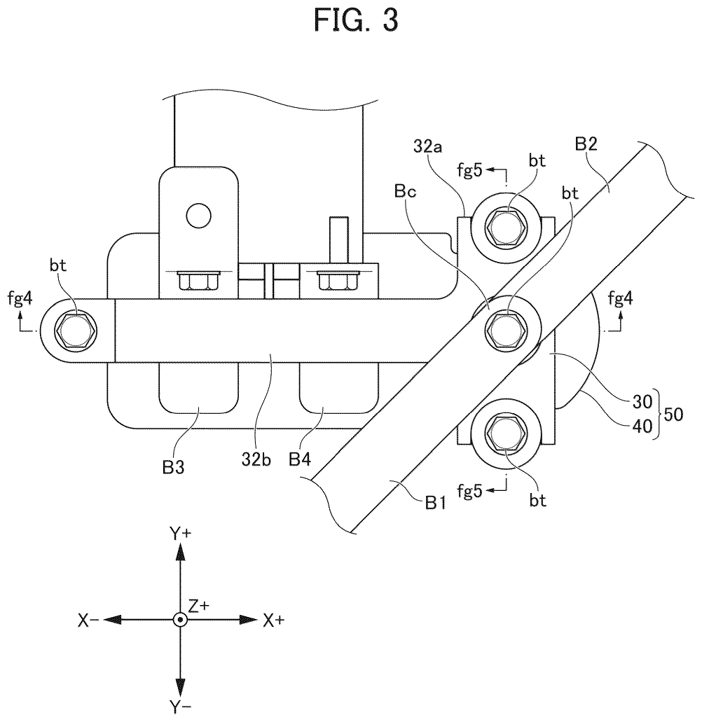

The four bus bars B1 to B4 include a first bus bar B1, a second bus bar B2, a third bus bar B3, and a fourth bus bar B4 shown in FIG. 2. Each of the four bus bars B1 to B4 is a conductor for electrically connecting a predetermined portion to another portion. As shown in FIG. 3, one end portion of the first bus bar B1 and one end portion of the second bus bar B2 are electrically connected to each other. Hereinafter, portions of the first bus bar B1 and the second bus bar B2 electrically connected to each other are referred to as a “bus bar connection portion Bc”.

As shown in FIG. 1, the bus bar connection structure 50 includes a terminal block 30 and a heat transfer sheet 40. The heat transfer sheet 40 is a sheet being an insulator, and is provided along the surface on the Z+ side, of a base 70 being a conductor. The terminal block 30 is provided on the Z+ side with respect to the heat transfer sheet 40. As shown in FIG. 3, the terminal block 30 is a member for supporting the bus bar connection portion Bc.

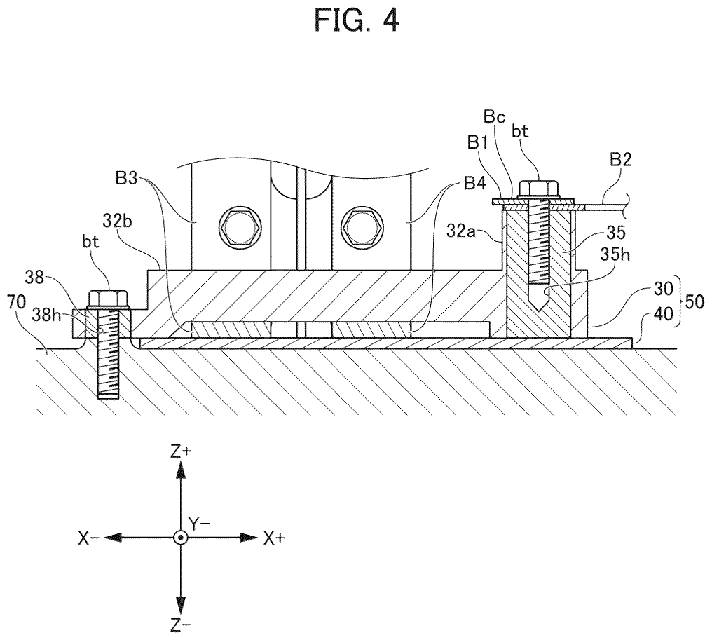

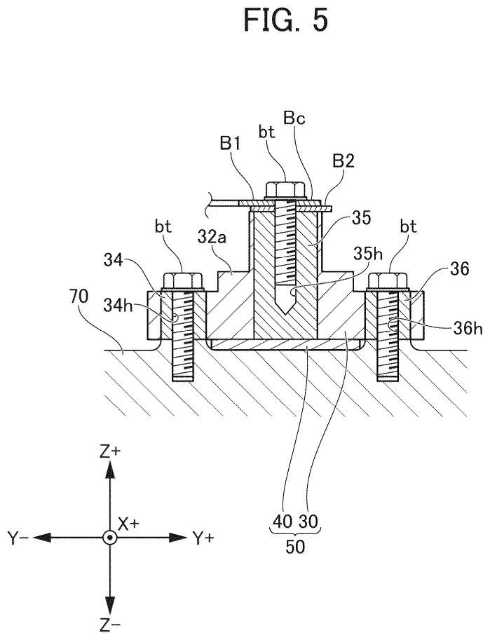

As shown in FIG. 1, the terminal block 30 includes a terminal block body 32a, a protruding portion 32b, and a heat transfer portion 35. Further, the terminal block 30 includes a first fastening portion 34 and a second fastening portion 36 as shown in FIG. 5, and a third fastening portion 38 as shown in FIG. 4. Hereinafter, the first fastening portion 34, the second fastening portion 36, and the third fastening portion 38 will be referred to as “fastening portions 34, 36, and 38”.

The terminal block body 32a and the protruding portion 32b shown in FIG. 1 are insulators such as resin and are integrally formed. The heat transfer portion 35 and the three fastening portions 34, 36, and 38 shown in FIGS. 4 and 5 are conductors such as metal.

As shown in FIG. 5, the terminal block body 32a extends in the Y direction. The first fastening portion 34, the heat transfer portion 35, and the second fastening portion 36 are attached to the terminal block body 32a in this order from the Y− side toward the Y+ side so as to be exposed on both sides in the Z direction.

The first fastening portion 34 and the second fastening portion 36 are provided with bolt through holes 34h and 36h that penetrate in the Z direction. Accordingly, the first fastening portion 34 and the second fastening portion 36 are configured to be fastened to the base 70 by bolts bt at both side portions of the terminal block body 32a sandwiching the heat transfer portion 35 in the Y direction. Actually, the first fastening portion 34 and the second fastening portion 36 are fastened to the base 70 by the bolts bt.

The heat transfer portion 35 is provided with a female screw hole 35h that opens to the Z+ side. Accordingly, the heat transfer portion 35 is configured such that the bus bar connection portion Bc can be fastened to the end portion thereof on the Z+ side by the bolt bt. Actually, the bus bar connection portion Bc is fastened to the end portion of the heat transfer portion 35 on the Z+ side by the bolt bt.

As shown in FIG. 1, the protruding portion 32b protrudes to the X-side from an intermediate portion in the Y direction, of the terminal block body 32a. As shown in FIG. 4, the third fastening portion 38 is attached to the end portion on the X-side, of the protruding portion 32b so as to be exposed on both sides in the Z direction. The third fastening portion 38 is provided with a bolt through hole 38h penetrating in the Z direction. Accordingly, the third fastening portion 38 is configured to be fastened to the base 70 by the bolt bt at the end portion on the X− side, of the protruding portion 32b. Actually, the third fastening portion 38 is fastened to the base 70 by the bolt bt.

As shown in FIG. 5, the heat transfer sheet 40 is interposed between the heat transfer portion 35 and the base 70. As a result, the bus bar connection portion Bc being a conductor is electrically insulated from and heat transferably connected to the base 70 being a conductor via the heat transfer portion 35 being a conductor and the heat transfer sheet 40 being an insulator.

As shown in FIG. 4, the third bus bar B3 and the heat transfer sheet 40 are interposed in this order from the Z+ side between the base 70 and a portion of the protruding portion 32b on the X+ side with respect to the third fastening portion 38. Further, the fourth bus bar B4 and the heat transfer sheet 40 are interposed in this order from the Z+ side between the base 70 and a portion of the protruding portion 32b on the X+ side with respect to the portion in contact with the third bus bar B3. Accordingly, the third and fourth bus bars B3 and B4 being conductors are electrically insulated from and heat transferably connected to the base 70 being a conductor via the heat transfer sheet 40 being an insulator.

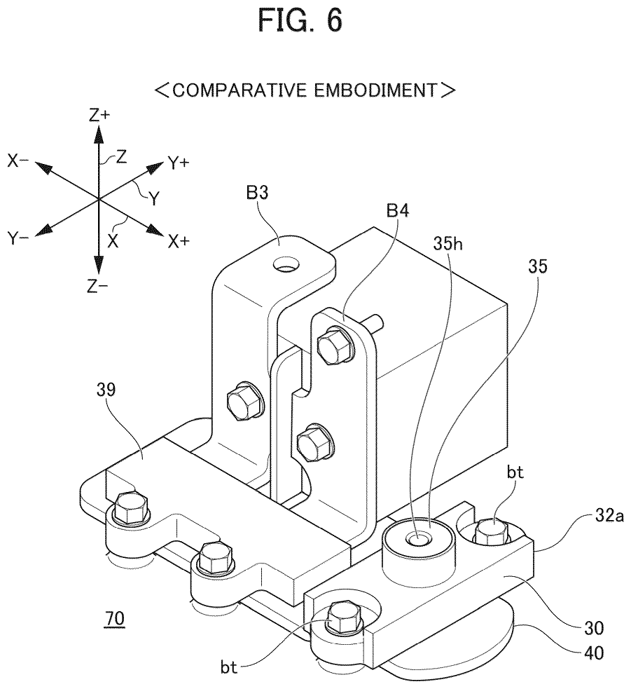

Hereinafter, an embodiment in which the protruding portion 32b of the present embodiment shown in FIG. 1 is eliminated and a pressing member 39 shown in FIG. 6 is provided instead will be referred to as a comparative embodiment. The pressing member 39 is a member dedicated to pressing the third bus bar B3 and the fourth bus bar B4 against the heat transfer sheet 40.

Hereinafter, the configuration and effects of the present embodiment will be summarized in comparison with the comparative embodiment.

According to the present embodiment, as shown in FIG. 4, the third bus bar B3 and the fourth bus bar B4 can be pressed against the heat transfer sheet 40 by the protruding portion 32b of the terminal block 30 for supporting the bus bar connection portion Bc to promote cooling. Accordingly, the terminal block 30 and the pressing member 39 in the comparative embodiment shown in FIG. 6 can be integrated into one terminal block 30 as shown in FIG. 1. As a result, the peripheral structure of the terminal block 30 can be simplified.

As shown in FIG. 5, the first fastening portion 34 and the second fastening portion 36 respectively provided in side portions of the terminal block body 32a that sandwich the heat transfer portion in the Y direction are fastened to the base 70. As shown in FIG. 3, the protruding portion 32b protrudes to the X− side from an intermediate portion in the Y direction, of the terminal block body 32a. As shown in FIG. 4, the third fastening portion 38 in the protruding portion 32b is also fastened to the base 70. By attaching the three fastening portions 34, 36, and 38 arranged in a distributed manner to the base 70, the terminal block 30 is fastened to the base 70 in a well-balanced manner as shown in FIG. 1.

As shown in FIG. 1, the terminal block body 32a and the protruding portion 32b are integrally formed. Accordingly, the configuration of the terminal block 30 can be simplified.

As shown in FIG. 4, a part of the heat transfer sheet 40 is interposed between the heat transfer portion 35 and the base 70. Another part of the heat transfer sheet 40 is interposed between the protruding portion 32b and the base 70. As described above, the heat transfer sheet interposed between the heat transfer portion 35 and the base 70 and the heat transfer sheet interposed between the protruding portion 32b and the base 70 are integrated into one predetermined heat transfer sheet 40, whereby the number of components of the bus bar connection structure 50 can be reduced.

### OTHER EMBODIMENTS

The embodiment described above can be modified as follows, for example.

The Z direction shown in FIG. 1 may be a direction diagonal to the vertical direction, and at least one of the X direction and the Y direction may be a direction diagonal to the horizontal direction. The Z direction may be the horizontal direction, and one of the X direction and the Y direction may be the vertical direction.

The portion interposed between the heat transfer portion 35 and the base 70, of the heat transfer sheet 40 shown in FIG. 1 and the portion interposed between the protruding portion 32b and the base 70, of the heat transfer sheet 40 may be separated from each other to form different heat transfer sheets.

The fourth bus bar B4 may not be provided, and the protruding portion 32b may press only the third bus bar B3 against the heat transfer sheet 40. In addition to the third bus bar B3 and the fourth bus bar B4, the protruding portion 32b may press further one or more bus bars against the heat transfer sheet 40.

### EXPLANATION OF REFERENCE NUMERALS

30 terminal block
32a terminal block body
32b protruding portion
35 heat transfer portion
40 heat transfer sheet
50 bus bar connection structure
70 base
B1 first bus bar (bus bar)
B2 second bus bar (bus bar)
B3 third bus bar (other bus bar)
B4 fourth bus bar (other bus bar)
Bc bus bar connection portion

What is claimed is:

1. A terminal block for supporting a bus bar connection portion as a connection portion between a plurality of bus bars, the terminal block comprising:
a terminal block body, being an insulator, configured to be fastened to a base, being a conductor, from a Z+ side as one side in a predetermined Z direction;
a heat transfer portion, being a conductor, that is attached to the terminal block body so as to be exposed on both sides in the Z direction from the terminal block body and that is configured such that the bus bar connection portion can be fastened to an end portion thereof on the Z+ side; and
a protruding portion, being an insulator, that protrudes from the terminal block body in an X direction orthogonal to the Z direction and that is configured to be fastened to the base,
wherein the terminal block is configured to allow a heat transfer sheet, being an insulator, to be interposed between the heat transfer portion and the base, and
wherein the terminal block is configured to allow a bus bar other than the plurality of bus bars and a heat transfer sheet, being an insulator, to be interposed between the protruding portion and the base, in this order from the Z+ side.

2. The terminal block according to claim 1,
wherein the terminal block body extends in a Y direction orthogonal to the X direction and the Z direction,
wherein both side portions of the terminal block body sandwiching the heat transfer portion in the Y direction are configured to be fastened to the base, and
wherein the protruding portion protrudes in the X direction from an intermediate portion in the Y direction, of the terminal block body.

3. The terminal block according to claim 1,
wherein the terminal block body and the protruding portion are integrally formed.

4. A bus bar connection structure comprising:
the terminal block according to claim 1,
wherein the heat transfer sheet, being the insulator, is interposed between the heat transfer portion and the base, and
wherein the bus bar other than the plurality of bus bars and the heat transfer sheet, being the insulator, are interposed between the protruding portion and the base, in this order from the Z+ side.

5. The bus bar connection structure according to claim 4,
wherein the heat transfer sheet interposed between the heat transfer portion and the base is a part of a predetermined heat transfer sheet, and
wherein the heat transfer sheet interposed between the protruding portion and the base is an other part of the predetermined heat transfer sheet.
